(19) United States
(12) Patent Application Publication
(10) Pub. No.: US 2009/0311808 A1
(43) Pub. Date: Dec. 17, 2009

(54) METHOD FOR PRODUCING SEMICONDUCTOR WAFER

(75) Inventors: Tomohiro Hashii, Tokyo (JP); Yuichi Kakizono, Tokyo (JP)

Correspondence Address: FITZPATRICK CELLA HARPER & SCINTO, 1290 Avenue of the Americas, NEW YORK, NY, 10104-3800, US

(73) Assignee: SUMCO CORPORATION, Tokyo (JP)

(21) Appl. No.: 12/475,816

(22) Filed: Jun. 1, 2009

(30) Foreign Application Priority Data
Jun. 16, 2008 (JP) 2008-157272

(51) Int. Cl. H01L 21/66; H01L 21/306

(52) U.S. Cl. 438/8; 438/691; 257/E21.219; 257/E21.53

(57) ABSTRACT

A semiconductor wafer is produced by a method comprising a slicing step, an one-side polishing step and a chemical treating step, in which the kerf loss is reduced and the flatness is improved.

### BACKGROUND OF THE INVENTION

1. Field of the Invention

This invention relates to a method for producing a semiconductor wafer, and more particularly to a method for producing a semiconductor wafer by cutting out a thin disc-shaped semiconductor wafer from a crystalline ingot and then subjecting both surfaces thereof to a mirror finishing.

2. Description of the Related Art

The conventional method for producing a semiconductor wafer typically comprises a series of a slicing step→a first beveling step→a lapping step→a second beveling step→a one-side grinding step→a double-sided polishing step→a one-side finish polishing step in this order.

In the slicing step, a thin disc-shaped semiconductor wafer is cut out from a crystalline ingot. In the first beveling step, an outer peripheral portion of the cut semiconductor wafer is beveled to suppress the occurrence of cracking or chipping in the semiconductor wafer at the subsequent lapping step. In the lapping step, the beveled semiconductor wafer is lapped with a grindstone of, for example, #1000 to increase a flatness of the semiconductor wafer. In the second beveling step, an outer peripheral portion of the lapped semiconductor wafer is beveled to render an end face of the semiconductor into a given beveled form. In the one-side grinding step, one-side face of the beveled semiconductor wafer is grounded with a grindstone of, for example, #2000-8000 to approximate the thickness of the semiconductor wafer to a final thickness. In the double-sided polishing step, both surfaces of the one-side grounded semiconductor wafer is polished. In the one-side finish polishing step, a one-side surface of the double-sided polished semiconductor wafer as a device face is further subjected to finish polishing.

In the aforementioned conventional method, a double-sided mirror finished semiconductor wafer is produced through the two beveling steps, the lapping step and the one-side grinding step, so that there are problems that a kerf loss of a semiconductor material (loss of semiconductor material due to the increase of lapped scrap and one-side ground scrap) is brought about due to a large number of steps.

Particularly, the above problem is remarkable on a large-diameter semiconductor wafer such as a silicon wafer having a diameter of not less than 450 mm. For example, when a silicon wafer having a diameter of not less than 450 mm is produced at the same machining allowance as a currently major silicon wafer having a diameter of 300 mm, the kerf loss of the silicon wafer is 2.25 times.

In addition, when the above-mentioned lapping step is added to the production method for a silicon wafer having a diameter of not less than 450 mm, the size of the lapping apparatus is considerably grown, which will be brought question on a place of disposing the lapping apparatus or the like in the formulation of the production line.

In Japanese Patent No.3,328,193 is proposed a method for producing a semiconductor wafer which comprises a double-sided grinding step instead of the lapping step in the above conventional method.

In the production method of the semiconductor wafer disclosed in this patent document, the problem of growing the size of the lapping apparatus in the production of the large-diameter semiconductor wafer is solved and the first beveling step before the double-sided grinding step can be omitted, but the double-sided grinding step and the one-side grinding step are conducted, and hence the machining allowance of the silicon material is still large, which remains as a problem about the kerf loss.

Moreover, it is desired to improve the flatness of the semiconductor wafer, which will be anticipated to become more severer in future, by reducing the machining allowance of the semiconductor wafer.

### SUMMARY OF THE INVENTION

It is, therefore, an object of the invention to advantageously solve the above-mentioned problems and to provide a method of producing a semiconductor wafer wherein both surfaces of a semiconductor wafer cut out from a crystalline ingot can be mirror-finished by a simple process flow obtained by decreasing the number of production steps and also the semiconductor wafer can be obtained cheaply by reducing the machining allowance of silicon material in the wafer to reduce the kerf loss of the semiconductor material. Particularly, the invention develops a remarkable effect when the semiconductor wafer is a silicon wafer having a diameter of not less than 450 mm.

In order to solve the above problems, the inventors have made various studies about a method for producing a semiconductor wafer wherein the number of production steps when a semiconductor wafer cut out from a crystalline ingot is rendered into a double-sided mirror-finished semiconductor wafer is decreased but also silicon kerf loss in the semiconductor wafer is reduced as compared with those of the conventional method.

As a result, it has been found that the number of production steps can be decreased but also the machining allowance of the semiconductor wafer can be reduced as compared with the conventional method by conducting a first sheet-feed type chemical treating step to a first one-side face of a semiconductor wafer instead of the lapping step and one-side grinding step in the conventional method, subjecting a first one-side face of the semiconductor wafer after the first sheet-feed type chemical treating step to a first one-side finish polishing step, observing the nature of the semiconductor wafer to conduct a second sheet-feed type chemical treating step of a second one-side face of the semiconductor wafer under adequate conditions based on the observation result, and subjecting the second one-side face of the semiconductor wafer after the second sheet-feed type chemical treating step to a second one-side finish polishing step.

The invention is based on the above knowledge and the summary and construction thereof are as follows.

1. A method for producing a semiconductor wafer, comprising a slicing step of cutting out a thin disc-shaped semiconductor wafer from a crystalline ingot; an one-side polishing step being subjected to both surfaces of the semiconductor wafer, respectively; and a chemical treating step of simultaneously conducting a reduction of working strain on one side or both sides of the semiconductor wafer and an finish beveling of making an end face of the semiconductor wafer into a given beveled form.

2. A method for producing a semiconductor wafer, comprising a slicing step of cutting out a thin disc-shaped semiconductor wafer from a crystalline ingot; a first sheet-feed type chemical treating step of rotating the semiconductor wafer while adding dropwise an etching solution to a first one-side face of the semiconductor wafer to simultaneously conduct reduction of working strain on the first one-side face and on an end face of the semiconductor wafer and finish beveling of making an end face of the semiconductor wafer to a given beveled form; a first one-side finish polishing step being subjected to the first one-side face of the semiconductor wafer after the first sheet-feed type chemical treating step; a second sheet-feed type chemical treating step of rotating the semiconductor wafer while adding dropwise an etching solution to a second one-side face of the semiconductor wafer to simultaneously conduct reduction of working strain on the second one-side face and an end face of the semiconductor wafer and finish beveling of making an end face of the semiconductor wafer to a given beveled form; a second one side finish polishing step being subjected to the second-side face of the semiconductor wafer after the second sheet-feed type chemical treating step, wherein nature of the semiconductor wafer is observed after the first one-side finish polishing step, and the second sheet-feed type chemical treating step and the second one-side polishing step are conducted under adequate conditions based on the observation result.

3. A method for producing a semiconductor wafer according to the item 1 or 2, wherein the semiconductor wafer is a silicon wafer having a diameter of not less than 450 mm.

According to the production method of the semiconductor wafer according to the invention, a first one-side face of a semiconductor wafer is subjected to a first sheet-feed type chemical treating step, and the first one-side face of the semiconductor wafer after the first sheet-feed type chemical treating step is subjected to a first one-side finish polishing step, and the nature of the semiconductor wafer is observed to conduct a second sheet-feed type chemical treating step of a second one-side face of the semiconductor wafer under adequate conditions based on the observation result, and then the second one-side face of the semiconductor wafer after the second sheet-feed type chemical treating step is subjected to a second one-side finish polishing step, whereby the number of production steps for the semiconductor wafer is shortened as compared with the conventional method and the machining allowance of the semiconductor wafer can be reduced to reduce the kerf loss of the semiconductor material to thereby obtain the semiconductor wafer cheaply.

Also, the flatness of the semiconductor wafer can be also improved by reducing the machining allowance of the semiconductor wafer. Furthermore, a semiconductor wafer having an epitaxial layer can be obtained by conducting an epitaxial layer growing step after the chemical treating step or the one-side finish polishing step. The production method of the semiconductor wafer according to the invention is especially suitable for the production of semiconductor wafers having a diameter of not less than 450 mm.

### BRIEF DESCRIPTION OF THE DRAWINGS

The invention will be described with reference to the accompanying drawings, wherein:

FIG. 1 is a flow chart showing production steps according to one embodiment of the invention;

FIG. 2 is a flow chart showing production steps of Conventional Example 1; and

FIG. 3 is a flow chart showing production steps of Conventional Example 2.

### DESCRIPTION OF THE PREFERRED EMBODIMENTS

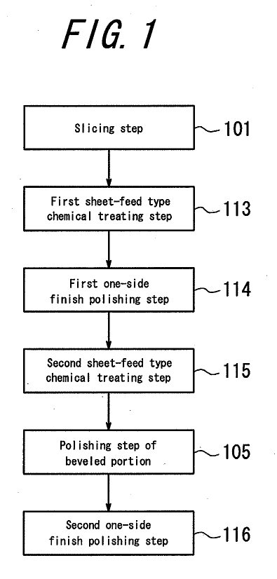

In FIG. 1 is shown a flow chart showing production steps according to one embodiment of the invention. In this embodiment, the following five steps (1)-(5) are conducted in this order:

(1) a slicing step of cutting out a thin disc-shaped semiconductor wafer from a crystalline ingot;

(2) a first sheet-feed type chemical treating step of rotating the semiconductor wafer while adding dropwise an etching solution to a first one-side face of the semiconductor wafer to simultaneously conduct reduction of working strain on the first one-side face and on an end face of the semiconductor wafer and finish beveling of making an end face of the semiconductor wafer to a given beveled form;

(3) a first one-side finish polishing step being subjected to the first one-side face of the semiconductor wafer after the first sheet-feed type chemical treating step;

(4) a second sheet-feed type chemical treating step wherein the nature of the semiconductor wafer is observed after the first one-side finish polishing step, and the semiconductor wafer is rotated while adding dropwise an etching solution to a second one-side face of the semiconductor wafer under adequate conditions based on the observation result to simultaneously conduct reduction of working strain on the second one-side face and an end face of the semiconductor wafer and finish beveling of making an end face of the semiconductor wafer to a given beveled form; and

(5) a second one side finish polishing step being subjected to the second-side face of the semiconductor wafer after the second sheet-feed type chemical treating step.

Next, the each step in the embodiment of the invention will be described.

(Slicing Step)

The slicing step is a step of cutting out a thin disc-shaped wafer by contacting a wire saw with a crystalline ingot while supplying a grinding solution, or by cutting a crystalline ingot with an inner diameter blade. In the production method of the semiconductor wafer according to the invention, “undulation” of the semiconductor wafer generated in the slicing step can not be removed by grinding the semiconductor wafer. Therefore, the semiconductor wafer after the slicing step is preferable to have a flatness of not more than 5 μm.

Moreover, the crystalline ingot is typically an ingot of silicon single crystal, but may be polycrystalline silicon for solar cells.

(Chemical Treating Step)

The chemical treating step simultaneously conducts reduction of working strain on the surfaces and end face of the semiconductor wafer applied at the slicing step and a finish beveling of making the end face of the semiconductor wafer to a given beveled form, which may be either a batch type or a sheet-feed type chemical treatment.

The batch type chemical treatment is a treatment of immersing a plurality of semiconductor wafers (e.g. 24 wafers) into a vessel containing a given etching solution to simultaneously conduct the reduction of working strain on both surfaces and end faces of the semiconductor wafer and the finish beveling of making the end face of the semiconductor wafer to a given beveled form.

The sheet-feed type chemical treating step is a treatment that one semiconductor wafer is rotated while adding dropwise an etching solution to a one-side face of the semiconductor wafer, whereby the etching solution is extended over the both surfaces and end faces of the semiconductor wafer through centrifugal force to reduce working strain on both the surfaces and end faces of the semiconductor wafer, and at the same time the end face of the semiconductor wafer is subjected to a finish beveling to a given beveled form.

As the etching solution used in the sheet-feed type chemical treatment, it is preferable to use a mixed acid of hydrofluoric acid, nitric acid and phosphoric acid, because it is required that when the etching solution is added dropwise to the rotating semiconductor wafer, it is extended over the surface of the semiconductor wafer to be etched at a proper rate to form a uniform film of the etching solution on this surface. A mixed acid of hydrofluoric acid, nitric acid and acetic acid usually used in an immersion etching is not preferable because it is low in the viscosity and when it is added dropwise to the rotating semiconductor wafer, a rate of extending over the surface to be etched is too fast and the film of the etching solution is not formed, resulting in irregular etching.

Moreover, the mixed acid of hydrofluoric acid, nitric acid and phosphoric acid used in the sheet-feed type chemical treatment is preferable to comprise 5˜20 mass % of hydrofluoric acid, 5˜40 mass % of nitric acid, and 30˜40 mass % of phosphoric acid.

The sheet-feed type chemical treatment is conducted twice through a one-side finish polishing step to etch both the surfaces of the semiconductor wafer. In order to render the end face of the semiconductor wafer into a given form after the two etching steps, the nature of the end face of the semiconductor wafer is observed at a time of completing the first sheet-feed type chemical treating step and the first one-side finish polishing to set conditions for the second sheet-feed type chemical treating step and the second one-side finish polishing step.

(One-Side Finish Polishing Step)

In the one-side finish polishing step, the chemically treated semiconductor wafer is polished with an abrasive cloth made of urethane or the like while supplying an abrasive slurry. The kind of the abrasive slurry is not particularly limited, but colloidal silica having a particle size of not more than 0.5 μm is preferable.

The one-side finish polishing step is conducted twice through the sheet-feed type chemical treating step to render the both surfaces of the semiconductor wafer into finish polished states. In the production method of the semiconductor wafer according to the invention, the thickness of the double-sided mirror polished semiconductor wafer is substantially determined at the slicing step because there is no grinding step, so that the fine adjustment of the thickness of the semiconductor wafer may be carried out in the one-side finish polishing step. If the fine adjustment is needed, the thickness of the semiconductor wafer is measured at a time of completing the first sheet-feed type chemical treating step and the first one-side finish polishing to determine conditions for the second one-side finish polishing step.

Although the above is described with respect to the main steps in the production method according to the invention, a polishing step of beveled portion and/or an epitaxial layer growing step may be included, if desired. The polishing step of beveled portion and the epitaxial layer growing step will be described below.

(Polishing Step of Beveled Portion)

The polishing step of the beveled portion is conducted after the second sheet-feed type chemical treating step for polishing the beveled portion of the semiconductor wafer to reduce a variation of the beveled width in the wafer. In this case, the beveled portions is polished with an abrasive cloth made of urethane or the like while supplying an abrasive slurry. The kind of the abrasive slurry is not particularly limited, but colloidal silica having a particle size of about 0.5 μm is preferable.

(Epitaxial Layer Growing Step)

A semiconductor wafer having an epitaxial layer can be obtained by conducting an epitaxial layer growing step after any of the first and second sheet-feed type chemical treating steps and the first and second one-side finish polishing steps. When the epitaxial layer is grown on the surface of the semiconductor wafer, it is required to remove surface damage of the semiconductor wafer applied at the slicing step, so that the epitaxial layer growing step is preferable to be conducted after any of the first and second sheet-feed type chemical treating steps and the first and second one-side finish polishing steps.

Although the above is merely described with respect to one embodiment of the invention, various modifications may be made without departing from the scope of the appended claims.

A semiconductor wafer is prepared by the production method according to the invention as stated below.

### INVENTION EXAMPLE 1

A silicon wafer having a diameter of 300 mm is prepared according to a process flow shown in FIG. 1 according to the invention.

### INVENTION EXAMPLE 2

A silicon wafer having a diameter of 450 mm is prepared in the same production method as in Invention Example 1.

### CONVENTIONAL EXAMPLE 1

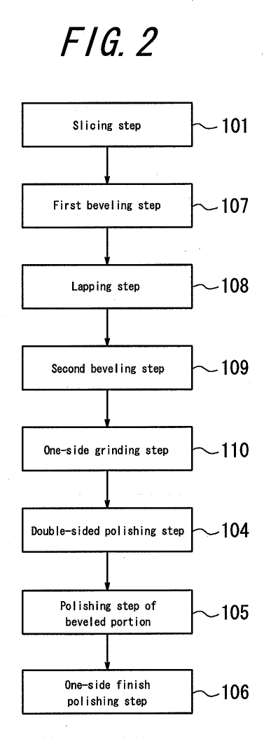

A silicon wafer having a diameter of 300 mm is prepared by the conventional production method shown in FIG. 2 inclusive of a lapping step.

### CONVENTIONAL EXAMPLE 2

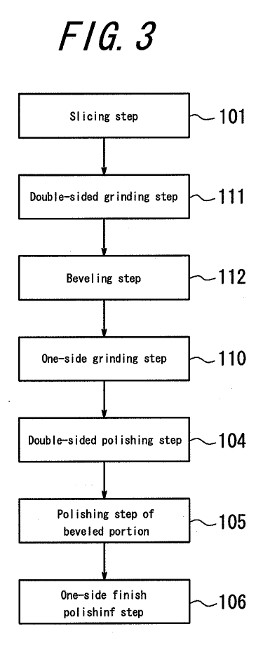

A silicon wafer having a diameter of 300 mm is prepared by a production method shown in FIG. 3 using a double-sided polishing step instead of the lapping step.

With respect to each of the thus obtained samples are evaluated the silicon kerf loss and flatness. The evaluation method will be described below.

(Silicon Kerf Loss)

The silicon kerf loss is evaluated by a reduction quantity (μm) of a thickness in the semiconductor wafer before the first sheet-feed type chemical treating step and after the second one-side finish polishing step in Invention Examples 1 and 2, a reduction quantity (μm) of a thickness in the semiconductor wafer before the first beveling step and after the one-side finish polishing step in Conventional Example 1, and a reduction quantity (μm) of a thickness in the semiconductor wafer before the double-sided grinding step and after the one-side finish polishing step in Conventional Example 2, respectively.

(Flatness)

The flatness of each sample is measured with a capacitance type thickness sensing meter and is evaluated as follows:
◯: less than 0.5 μm.
Δ: not less than 0.5 μm but not more than 1 μm.
×: more than 1 μm.

The evaluation results of the samples are shown in Table 1.

TABLE 1

| | Invention | Invention | Conventional | Conventional |
|---|---|---|---|---|
| | Example 1 | Example 2 | Example 1 | Example 2 |
| Process Flow | FIG. 1 | FIG. 1 | FIG. 2 | FIG. 3 |
| Diameter (mm) | 300 | 450 | 300 | 300 |
| Silicon kerf loss | 40 | 40 | 100 | 105 |
| (ground thickness: | | | | |
| μm) | | | | |
| Flatness | ◯ | ◯ | Δ | Δ |

As seen from Table 1, Invention Example 1 shows a minimum value of the silicon kerf loss and a good flatness, and Invention Example 2 shows good results substantially equal to those of Invention Example 1, from which it has been confirmed that a silicon wafer having a diameter of 450 mm is obtained by the production method according to the embodiment of the invention. On the other hand, Conventional Examples 1 and 2 show a large silicon kerf loss and a poor flatness as compared with Invention Examples 1 and 2.

According to the production method of the semiconductor wafer according to the invention, a first one-side face of a semiconductor wafer is subjected to a first sheet-feed type chemical treating step, and the first one-side face of the semiconductor wafer after the first sheet-feed type chemical treating step is subjected to a first one-side finish polishing step, and the nature of the semiconductor wafer is observed to conduct a second sheet-feed type chemical treating step of a second one-side face of the semiconductor wafer under adequate conditions based on the observation result, and then the second one-side face of the semiconductor wafer after the second sheet-feed type chemical treating step is subjected to a second one-side finish polishing step, whereby the number of production steps for the semiconductor wafer is shortened as compared with the conventional method and the machining allowance of the semiconductor wafer can be reduced to reduce the kerf loss of the semiconductor material to thereby obtain the semiconductor wafer cheaply.

Also, the flatness of the semiconductor wafer can be also improved by reducing the machining allowance of the semiconductor wafer. Furthermore, a semiconductor wafer having an epitaxial layer can be obtained by conducting an epitaxial layer growing step after the chemical treating step or the one-side finish polishing step. The production method of the semiconductor wafer according to the invention is especially suitable for the production of semiconductor wafers having a diameter of not less than 450 mm.

What is claimed is:

1. A method for producing a semiconductor wafer, comprising
a slicing step of cutting out a thin disc-shaped semiconductor wafer from a crystalline ingot;
an one-side polishing step being subjected to both surfaces of said semiconductor wafer, respectively;
and a chemical treating step of simultaneously conducting a reduction of working strain on one side or both sides of said semiconductor wafer and a finish beveling of making an end face of said semiconductor wafer into a given beveled form.

2. A method for producing a semiconductor wafer, comprising
a slicing step of cutting out a thin disc-shaped semiconductor wafer from a crystalline ingot;
a first sheet-feed type chemical treating step of rotating said semiconductor wafer while adding dropwise an etching solution to a first one-side face of said semiconductor wafer to simultaneously conduct reduction of working strain on said first one-side face and on an end face of said semiconductor wafer and finish beveling of making an end face of said semiconductor wafer to a given beveled form;
a first one-side finish polishing step being subjected to said first one-side face of said semiconductor wafer after said first sheet-feed type chemical treating step;
a second sheet-feed type chemical treating step of rotating said semiconductor wafer while adding dropwise an etching solution to a second one-side face of said semiconductor wafer to simultaneously conduct reduction of working strain on said second one-side face and an end face of said semiconductor wafer and finish beveling of making an end face of said semiconductor wafer to a given beveled form;
a second one side finish polishing step being subjected to said second-side face of said semiconductor wafer after said second sheet-feed type chemical treating step,
wherein nature of said semiconductor wafer is observed after said first one-side finish polishing step, and said second sheet-feed type chemical treating step and said second one-side polishing step are conducted under adequate conditions based on said observation result.

3. A method for producing a semiconductor wafer according to claim 1 or 2, wherein said semiconductor wafer is a silicon wafer having a diameter of not less than 450 mm.
